(19) United States
(12) Patent Application Publication
(10) Pub. No.: US 2023/0124778 A1
(43) Pub. Date: Apr. 20, 2023

(54) SEMICONDUCTOR DEVICE AND METHOD FOR MANUFACTURING SEMICONDUCTOR DEVICE

(71) Applicant: FUJI ELECTRIC CO., LTD., Kawasaki-shi (JP)

(72) Inventors: Akito NAKAGOME, Matsumoto-city (JP); Katsumi TANIGUCHI, Matsumoto-city (JP); Ryoichi KATO, Matsumoto-city (JP); Yuma MURATA, Matsumoto-city (JP)

(73) Assignee: FUJI ELECTRIC CO., LTD., Kawasaki-shi (JP)

(21) Appl. No.: 17/954,166

(22) Filed: Sep. 27, 2022

(30) Foreign Application Priority Data
Oct. 20, 2021 (JP) 2021-171319

(51) Int. Cl. H01L 23/498; H01L 23/64; H01L 21/48; H01L 23/482

(52) U.S. Cl. CPC H01L 23/49844; H01L 23/49811; H01L 23/49822; H01L 23/49894; H01L 23/642; H01L 21/4853; H01L 21/4857; H01L 23/4822

(57) ABSTRACT

A semiconductor module (semiconductor device) includes a case that has a side wall to form a frame, the side wall having a concave portion, a multi-layer structure in which a first terminal, an insulating sheet, and a second terminal are stacked in that order and which is disposed on the concave portion, and a beam member that is attached to the concave portion of the case to fix the multi-layer structure disposed on the concave portion.

### CROSS-REFERENCE TO RELATED APPLICATION

This application is based upon and claims the benefit of priority of the prior Japanese Patent Application No. 2021-171319, filed on Oct. 20, 2021, the entire contents of which are incorporated herein by reference.

### BACKGROUND OF THE INVENTION

### 1. Field of the Invention

The embodiments discussed herein relate to a semiconductor device and a method for manufacturing a semiconductor device.

### 2. Background of the Related Art

One known technology relating to semiconductor devices houses a semiconductor unit, which includes a ceramic circuit board and a semiconductor chip mounted on the circuit board, in a case made of a resin material such as polyphenylene sulfide (PPS) resin, the case being provided with a multi-layer terminal portion in which a first power terminal, an insulating material, and a second power terminal are stacked in that order (see the specification of U.S. Patent Application Publication No. 2021/0202372).

In another known technology, a terminal block where a plurality of main terminals and insulating paper inserted between the respective main terminals are fixed to a resin line is provided inside the case of a semiconductor device. The terminal block is formed by forming holes in the main terminals and the insulating paper and by fixing the main terminals and the insulating paper to the resin line by integrated molding with resin that enters the holes during molding of the resin line using a mold (see Japanese Laid-open Patent Publication No. 2004-153243).

One known semiconductor device includes a multi-layer terminal portion in which a first power terminal, a first insulating sheet, and a second power terminal are stacked in that order, where the first power terminal has a first bonding region that is conductively connected to a first connection terminal of a capacitor, the second power terminal has a second bonding region that is conductively connected to a second connection terminal of the capacitor, and the first insulating sheet has a terrace part that extends in a direction from the second bonding region toward the first bonding region in plan view (see Japanese Laid-open Patent Publication No. 2021-106235).

In a semiconductor device with a case provided with a multi-layer structure where a first terminal, an insulating sheet, and a second terminal are stacked in that order, as one example, the multi-layer structure may be insertion molded when molding with the case resin material. However, with this method, when an insulating material with a low withstand temperature compared to the molding temperature of the case resin material is used for the insulating sheet included in the multi-layer structure, there is the risk of the insulating sheet deteriorating due to contact with the case resin material that reaches a comparatively high temperature during molding. When the insulating sheet deteriorates, this may result in problems in achieving sufficient insulation between the first terminal and the second terminal provided on both sides of the insulating sheet. This makes it difficult to ensure the reliability of a semiconductor device where a multi-layer structure formed of the first terminal, the insulating sheet, and the second terminal is provided on the case.

### SUMMARY OF THE INVENTION

According to one aspect, there is provided a semiconductor device including: a case that has a side wall to form a frame, the side wall having a concave portion; a multi-layer structure in which a first terminal, an insulating sheet, and a second terminal are stacked in that order and which is disposed on the concave portion; and a beam member that is attached to the concave portion of the case to fix the multi-layer structure disposed on the concave portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 depicts one example of a semiconductor device according to a first embodiment;

FIG. 2 depicts one example of connected parts of the semiconductor module and a capacitor according to the first embodiment;

FIG. 3 depicts one example of the semiconductor module according to the first embodiment;

FIGS. 4A to 4C depict one example of a case of the semiconductor module according to the first embodiment;

FIGS. 5A to 5C depict one example of a multi-layer structure of a semiconductor module according to the first embodiment;

FIGS. 6A to 6C depict one example of a beam member of a semiconductor module according to the first embodiment;

FIGS. 7A and 7B depict one example of a process that prepares a multi-layer structure according to the first embodiment;

FIG. 8 is a first diagram depicting one example of an assembly process of a case, multi-layer structures, and beam members according to the first embodiment;

FIGS. 9A and 9B are second diagrams depicting one example of the assembly process of the case, multi-layer structures, and beam members according to the first embodiment;

FIG. 10 depicts one example of a semiconductor module according to a second embodiment;

FIGS. 11A and 11B are first diagrams depicting examples of a semiconductor module according to a third embodiment;

FIG. 12 is a second diagram depicting an example of the semiconductor module according to the third embodiment;

FIGS. 13A and 13B depict one example of a semiconductor module according to a fourth embodiment;

FIGS. 14A and 14B are first diagrams depicting example configurations of a multi-layer structure of a semiconductor module according to a fifth embodiment;

FIGS. 15A and 15B are second diagrams depicting example configurations of a multi-layer structure of the semiconductor module according to the fifth embodiment; and

FIG. 16 depicts one example of a method for manufacturing a semiconductor module according to a sixth embodiment.

### DETAILED DESCRIPTION OF THE INVENTION

### First Embodiment

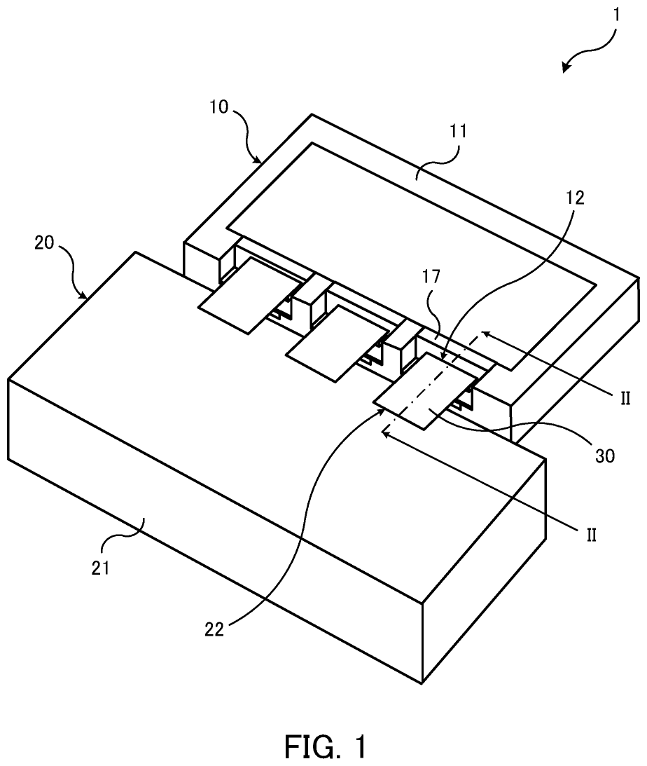

FIG. 1 depicts one example of a semiconductor device according to a first embodiment. FIG. 1 is a perspective view schematically depicting a principal part of one example of a semiconductor device.

A semiconductor device 1 depicted in FIG. 1 includes a semiconductor module (also referred to as a “semiconductor device”) 10, a capacitor 20, and connector members 30 that connect the semiconductor module 10 and the capacitor 20.

The semiconductor module 10 includes a case 11. The case 11 of the semiconductor module 10 houses an insulating substrate and semiconductor elements and the like mounted on the insulating substrate.

As one example, PPS resin is used here for the case 11 of the semiconductor module 10. As alternatives, polybutylene terephthalate (PBT) resin, polybutylene succinate (PBS) resin, polyamide (PA) resin, acrylonitrile butadiene styrene (ABS) resin, or the like may be used as the case 11 of the semiconductor module 10. The case 11 of the semiconductor module 10 may be formed by injection molding, for example, using the resin materials listed above.

One example of the insulating substrate housed in the case 11 of the semiconductor module 10 is a ceramic substrate with conductor layers provided in predetermined patterns on both main surfaces. As examples of the ceramic substrate, a substrate made of alumina, a composite ceramic containing alumina as a main component, aluminum nitride, or silicon nitride is used. Metal such as copper or aluminum is used for the conductor layers. As the insulating substrate, it is possible to use a direct copper bonding (DCB) substrate, an active metal brazed (AMB) substrate, or the like.

As examples, a semiconductor element such as an insulated gate bipolar transistor (IGBT) or a metal oxide semiconductor field effect transistor (MOSFET) is used as the semiconductor elements mounted on the insulating substrate housed inside the case 11 of the semiconductor module 10. As other examples of the semiconductor elements, a diode such as a free wheeling diode (FWD) or a Schottky barrier diode (SBD) may be used, or a device where one of these diodes is integrated with an IGBT or MOSFET may be used. As other components, a terminal component or the like to be connected to the semiconductor element(s) may be mounted on the insulating substrate.

Terminal structure portions 12 are provided on one edge of the case 11 of the semiconductor module 10 in which the insulating substrate and the semiconductor elements and the like mounted on the insulating substrate are housed. The terminal structure portions 12 are connected to the housed insulating substrate, semiconductor elements, and the like and connect the semiconductor module 10 to an external capacitor 20. Beam members 17 are further provided on one edge of the case 11. Here, as one example, the semiconductor module 10 that has three terminal structure portions 12 and beam members 17 provided on one side of the case 11 is depicted. Note that the terminal structure portions 12 and the beam members 17 of the semiconductor module 10 will be described later.

The capacitor 20 includes a case 21. The case 21 of the capacitor 20 internally houses capacitance elements.

Here, as one example, PPS resin is used for the case 21 of the capacitor 20. As alternatives, materials such as PBT resin, PBS resin, PA resin, and ABS resin may be used for the case 21 of the capacitor 20. The case 21 of the capacitor 20 may be formed by injection molding, for example, using the resin materials listed above.

Terminal structure portions 22 are provided on one edge of the case 21 of the capacitor 20 in which the capacitance elements are housed. The terminal structure portions 22 are connected to the housed capacitance elements and connect the capacitor 20 to the external semiconductor module 10. Here, as one example, three terminal structure portions 22 are provided on one edge of the case 21. Note that the terminal structure portions 22 of the capacitor 20 will be described later.

The semiconductor module 10 and the capacitor 20 are disposed so that the terminal structure portions 12 and the terminal structure portions 22 face each other, and the respective terminal structure portions 12 and terminal structure portions 22 are connected to each other using connector members 30 such as bus bars. By connecting the semiconductor module 10 and the capacitor 20 in this way, the semiconductor device 1 is realized.

In the semiconductor device 1, a circuit with a predetermined function, such as a power converter circuit or an inverter circuit, is formed using the insulating substrate of the semiconductor module 10 and the semiconductor element(s) and the like mounted on the insulating substrate and the capacitance elements of the capacitor 20.

Connected parts of the semiconductor module 10 and the capacitor 20 of the semiconductor device 1 will now be described.

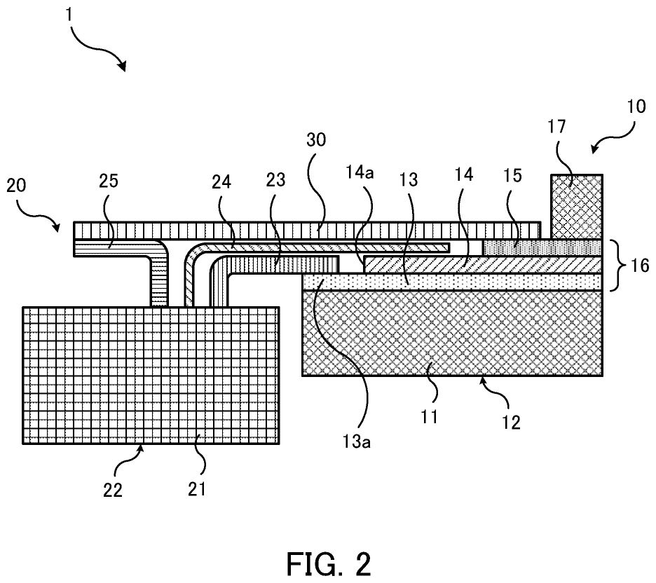

FIG. 2 depicts one example of connected parts of a semiconductor module and a capacitor according to the first embodiment. FIG. 2 is a schematic cross-sectional view taken along a line II-II in FIG. 1.

As one example, as depicted in FIG. 2, the case 11 of the semiconductor module 10 is provided with the terminal structure portions 12, which each include a multi-layer structure 16 where a terminal 13, an insulating sheet 14, and a terminal 15 are stacked in that order. As one example, the terminal 13 is a negative (N) terminal of the semiconductor module 10 and the terminal 15 is a positive (P) terminal of the semiconductor module 10. The terminal 13 and the terminal 15 are respectively connected to negative terminals and positive terminals of the insulating substrate housed inside the case 11, a semiconductor element, or a component connected to the insulating substrate and/or a semiconductor element. The terminal 13, the insulating sheet 14, and the terminal 15 are stacked so that the insulating sheet 14 is interposed between the terminal 13 and the terminal 15. Metal such as copper or aluminum is used as the terminal 13 and the terminal 15. An insulating resin material such as aramid resin, PA resin, fluororesin, or polyimide resin is used for the insulating sheet 14.

The terminal 13, the insulating sheet 14, and the terminal 15 of the multi-layer structure 16 are provided in a stacked arrangement so that the terminal 13, the insulating sheet 14, and the terminal 15 form a stepped arrangement when viewed in cross section as in FIG. 2. The multi-layer structure 16 including the terminal 13, insulating sheet 14, and terminal 15 that are stacked is fixed to the case 11 together with the beam member 17 provided above the multi-layer structure 16. Note that the case 11 and the multi-layer structure 16 and the beam member 17 fixed to the case 11 will be described later.

As one example, as depicted in FIG. 2, the case 21 of the capacitor 20 connected to the semiconductor module 10 is provided with the terminal structure portions 22, which each include a terminal 23, an insulating sheet 24, and a terminal 25. As one example, the terminal 23 is an N terminal of the capacitor 20 and the terminal 25 is a P terminal of the capacitor 20. Metal such as copper or aluminum is used as the terminal 23 and the terminal 25. An insulating resin material such as aramid resin, PA resin, fluororesin, or polyimide resin is used for the insulating sheet 24.

As one example, as depicted in FIG. 2, one end of the terminal 23 is connected to the case 21 and another end is bent toward an outside of the case 21. The terminal 25 is provided at a position on the case 21 that is closer to the inside of the case 21 than the terminal 23, has one end connected to the case 21, and has another end bent toward an inside of the case 21. The insulating sheet 24 has one end connected to a position on the case 21 that is between the terminal 23 and the terminal 25 and is flexible so as to be capable of bending toward the terminal 23. The insulating sheet 24 is sized so that when bent toward the terminal 23, the insulating sheet 24 is capable of covering the terminal 23.

The semiconductor module 10 and the capacitor 20 are disposed so that the terminal structure portions 12 of the case 11 and the terminal structure portions 22 of the case 21 face each other. One part (also referred to as a “connecting region”) 13a of the terminal 13 that is exposed from the insulating sheet 14 in a terminal structure portion 12 of the semiconductor module 10 and the terminal 23 of a terminal structure portion 22 of the capacitor 20 are connected together. As one example, the terminal 13 of the semiconductor module 10 and the terminal 23 of the capacitor 20 are both N terminals.

The terminals 13 of the semiconductor module 10 and the terminals 23 of the capacitor 20 are connected by laser welding, for example. This laser welding may be performed using a seam laser that continuously emits laser light or may be performed using a spot laser that emits pulsed laser light. Note that the terminals 13 of the semiconductor module 10 and the terminals 23 of the capacitor 20 may be connected by another method, such as soldering or ultrasonic bonding.

After the terminals 13 of the semiconductor module 10 and the terminals 23 of the capacitor 20 have been connected, the insulating sheets 24 of the capacitor 20 are bent toward the connected parts of the terminals 13 and the terminals 23. When the insulating sheets 24 of the capacitor 20 are bent in this way, the terminals 23, the connecting regions 13a of the terminals 13 connected to the terminal 23, and also the insulating sheets 14 become covered with the bent insulating sheets 24.

Note that although FIG. 2 depicts a state in which a bent insulating sheet 24 does not contact the terminal 23 of the capacitor 20 or the insulating sheet 14 of the semiconductor module 10 out of convenience, the bent insulating sheet 24 may contact the terminal 23 of the capacitor 20 and the insulating sheet 14 of the semiconductor module 10.

After the insulating sheets 24 of the capacitor 20 have been bent, the terminals 15 of the semiconductor module 10 and the terminals 25 of the capacitor 20 are connected using the connector members 30. Metal such as copper or aluminum is used for the connector members 30. As one example, bus bars are used as the connector members 30. The connector members 30 are disposed so as to straddle the insulating sheets 24 of the capacitor 20, which are themselves provided so as to cover the connected parts of the terminals 13 of the semiconductor module 10 and the terminals 23 of the capacitor 20 along with the insulating sheets 14 of the semiconductor module 10, and are connected to the terminals 15 of the semiconductor module 10 and the terminals 25 of the capacitor 20. As one example, the terminals 15 of the semiconductor module 10 and the terminals 25 of the capacitor 20 are both P terminals, and the connector members 30 are P terminal connector members that connect the P terminals of the semiconductor module 10 and the capacitor 20 to each other.

Note that although FIG. 2 depicts a state in which a connector member 30 does not contact the bent insulating sheet 24 out of convenience, the connector member 30 may contact the bent insulating sheet 24.

The terminal 15 of the semiconductor module 10 and the terminal 25 of the capacitor 20 may be connected to the connector member 30 by laser welding, for example. Laser welding may be performed using a seam laser or a spot laser. Note that the terminals 15 of the semiconductor module 10 and the terminals 25 of the capacitor 20 may be connected to the connector members 30 by another method, such as soldering or ultrasonic bonding.

By connecting the terminal structure portions 12 and the terminal structure portions 22 using the connector members 30 as described above for example, the semiconductor module 10 and the capacitor 20 are connected to each other.

Although the capacitor 20 is given here as an example of a component connected to the semiconductor module 10, the component connected to the semiconductor module 10 is not limited to the capacitor 20. It is possible to connect the semiconductor module 10 to various electronic components, such as a module or component with terminals that connect to the PN terminals of the semiconductor module 10.

The semiconductor module 10 will now be described further.

As described above, the semiconductor module 10 has the multi-layer structures 16, in which the terminal 13, the insulating sheet 14, and the terminal 15 are stacked in that order, on the case 11.

Here, as one method of providing the multi-layer structures 16 on the case 11, there is a conventional method where the multi-layer structures 16 are insertion molded using the same resin material as the case during molding of the case 11 using a resin material such as PPS resin. However, when the multi-layer structures 16 are insertion molded in this way, the insulating sheets 14 of the multi-layer structures 16 may contact the case resin material, such as PPS resin, which becomes relatively hot during molding. This means that when the insulating sheets 14 are made of an insulating material whose withstand temperature is lower than the molding temperature of the case resin material (which at the maximum is around 330° C. for example), the insulating sheets 14 may deteriorate due to contact with the case resin material that is a relatively high temperature during molding. When the insulating sheets 14 deteriorate, this may result in problems in achieving sufficient insulation between the terminals 13 and the terminals 15 provided on both sides of the insulating sheets 14. This makes it difficult to ensure the reliability of the semiconductor module 10 in which the multi-layer structures 16 formed of the terminal 13, the insulating sheet 14, and the terminal 15 are provided on the case 11.

To solve the problem described above, the semiconductor module 10 according to the first embodiment uses the configurations described above and below.

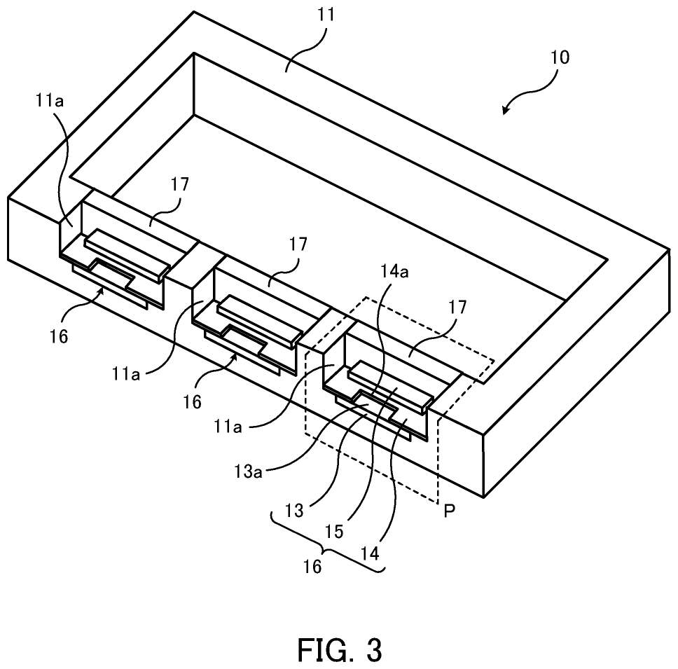

FIG. 3 depicts one example of a semiconductor module according to the first embodiment. FIG. 3 is a perspective view schematically depicting a principal part of one example of a semiconductor module.

As depicted in FIG. 3 (and also in FIGS. 1 and 2 described earlier), the semiconductor module 10 includes the case 11, the multi-layer structures 16, and the beam members 17. In this example, a case in the shape of a frame or a part of a case that is frame-shaped is depicted as the case 11. The case 11 is frame-shaped and has a concave portion 11a on one edge of the frame shape. The case 11 has a side wall to form the frame, and the side wall has the concave portion 11a. As one example, FIG. 3 depicts a case 11 with three concave portions 11a provided in one edge of a frame. Multi-layer structures 16, which is to say, multi-layer structures 16 in which the terminal 13, the insulating sheet 14, and the terminal 15 are stacked in that order, are disposed in the respective concave portions 11a of the case 11. A beam member 17 is then disposed and fixed in each concave portion 11a of the case 11 in which a multi-layer structure 16 has been placed, and the multi-layer structure 16 is fixed to the concave portion 11a by the beam member 17.

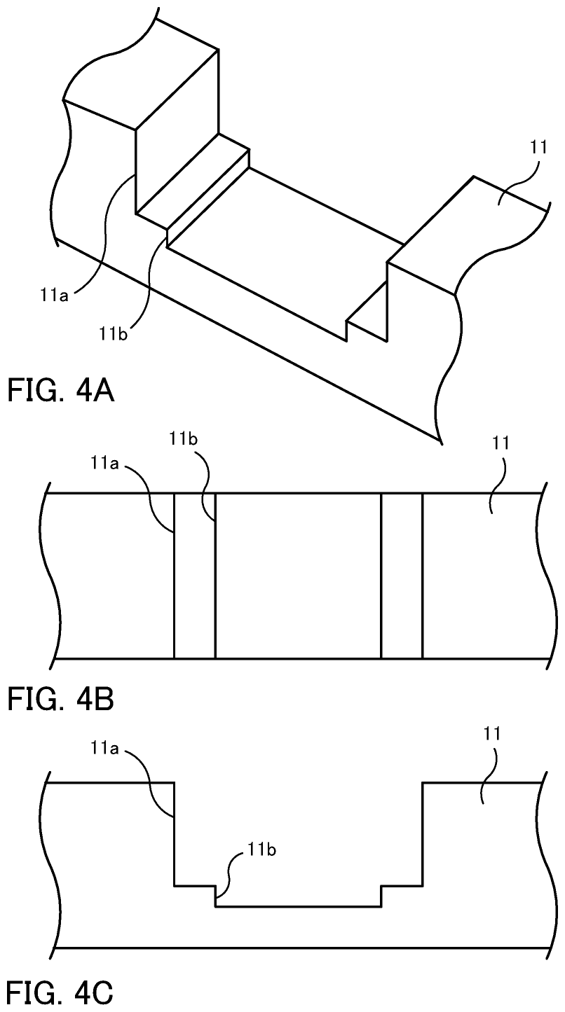

The case 11, the multi-layer structures 16, and the beam members 17 of the semiconductor module 10 will now be described further with reference to FIGS. 4A to 6C.

First, the case 11 of the semiconductor module 10 will be described with reference to FIGS. 4A to 4C.

FIGS. 4A to 4C depict one example of a case of a semiconductor module according to the first embodiment. FIG. 4A is a perspective view schematically depicting a principal part of an example case of a semiconductor module. FIG. 4B is a plan view schematically depicting a principal part of an example case of a semiconductor module. FIG. 4C is a side view schematically depicting a principal part of an example case of a semiconductor module.

FIGS. 4A to 4C schematically depict one example of a case 11 of the semiconductor module 10 in a part labelled P in FIG. 3. Concave portions 11a like that depicted in FIGS. 4A to 4C are provided in one edge of the frame-shaped case 11. The concave portion 11a is provided so as to pass through one edge of the case 11 in the inside/outside direction of the case 11, that is, to pass through the edge in a direction that is perpendicular to the direction in which the edge extends. The width of each concave portion 11a in the length direction of the edge is set at a width capable of accommodating the multi-layer structure 16 and the beam member 17 which are to be disposed in the concave portion 11a as described later.

As depicted in FIGS. 4A to 4C, each concave portion 11a of the case 11 is partially recessed at the bottom to form a recess 11b. The recess 11b at the bottom of the concave portion 11a is set at a width and depth capable of accommodating the terminal 13 of the multi-layer structure 16 to be disposed in the concave portion 11a as described later. That is, the terminal 13 of a multi-layer structure 16 is housed in the recess 11b provided at the bottom of the concave portion 11a. The parts of the bottom of the concave portion 11a where the recess 11b is not formed face the insulating sheet 14 of the multi-layer structure 16.

A resin material such as PPS resin, PBT resin, PBS resin, PA resin, or ABS resin is used for the case 11. The case 11, which is provided with the concave portions 11a that each have a recess 11b as described above, may be formed by injection molding, for example, using a predetermined resin material.

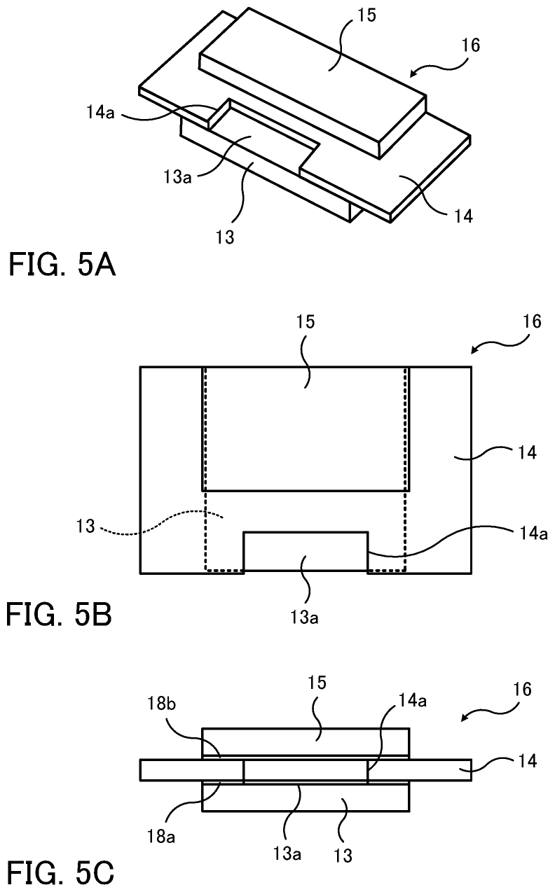

Next, the multi-layer structures 16 of the semiconductor module 10 will be described with reference to FIGS. 5A to 5C.

FIGS. 5A to 5C depict one example of a multi-layer structure of a semiconductor module according to the first embodiment. FIG. 5A is a perspective view schematically depicting a principal part of an example multi-layer structure of the semiconductor module. FIG. 5B is a plan view schematically depicting a principal part of an example multi-layer structure of the semiconductor module. FIG. 5C is a side view schematically depicting a principal part of an example multi-layer structure of the semiconductor module.

FIGS. 5A to 5C schematically depict one example of a multi-layer structure 16 of the semiconductor module 10 in a part labelled P in FIG. 3. Each multi-layer structure 16 is configured with the terminal 13, the insulating sheet 14, and the terminal 15 stacked in that order. As one example, the terminals 13 and 15 that face each other with the insulating sheet 14 in between have the same or a similar width in plan view and in side view as depicted in FIGS. 5B and 5C. As one example, the insulating sheet 14 interposed between the terminal 13 and the terminal 15 has a larger width than the terminal 13 and the terminal 15 in plan view and in side view as depicted in FIGS. 5B and 5C. The insulating sheet 14 that is wider than the terminal 13 and the terminal 15 is set at a width that is capable of being housed in the concave portion 11a of the case 11, for example, which is to say, equal to or narrower than the width of the concave portion 11a in the length direction of the edge of the case 11 in which the concave portion 11a is provided.

As one example, a cutout portion 14a is provided on one edge (a front end portion that becomes positioned outside the case 11) of the insulating sheet 14 as depicted in FIGS. 5A to 5C. The connecting region 13a of the terminal 13 is exposed from the cutout portion 14a of the insulating sheet 14. The terminal 13 is covered with the insulating sheet 14 in a state where the connecting region 13a is positioned at the cutout portion 14a of the insulating sheet 14. In this configuration, the terminal 13 is covered with the insulating sheet 14 except for the connecting region 13a positioned at the cutout portion 14a of the insulating sheet 14. The terminal 15 is provided on the insulating sheet 14, that is, on the opposite side of the insulating sheet 14 to the terminal 13 side. In plan view, the terminal 15 is provided at a position that faces the terminal 13 with the insulating sheet 14 in between but does not overlap the connecting region 13a. The terminal 15, the insulating sheet 14, and the connecting region 13a of the terminal 13 exposed from the cutout portion 14a of the insulating sheet 14 are in a stepped arrangement. As depicted in FIG. 5C, the terminal 13 is bonded to the insulating sheet 14 using an adhesive 18a (first second-adhesive), and the terminal 15 is bonded to the insulating sheet 14 using an adhesive 18b (second second-adhesive).

Out of a multi-layer structure 16, the connecting region 13a of the terminal 13 is connected for example to the terminal 23 of the capacitor 20 as described above, and the terminal 15 is connected for example to the connector member 30 which is connected to the terminal 25 of the capacitor 20 as described above.

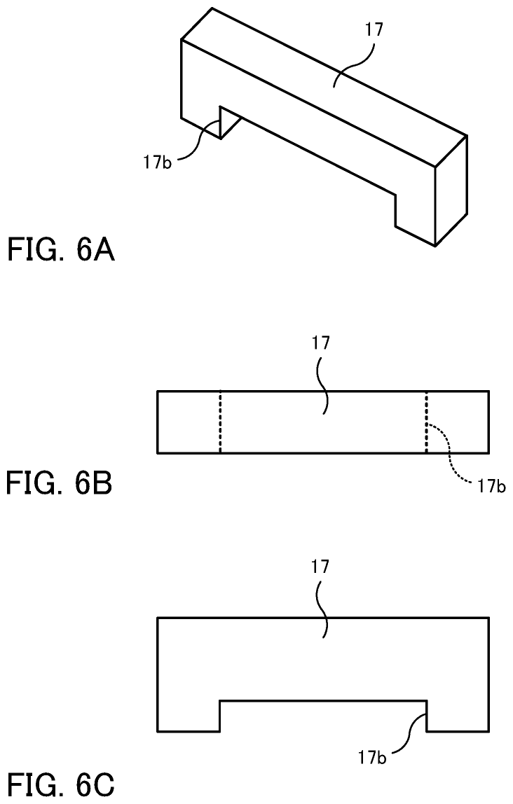

Next, the beam members 17 of the semiconductor module 10 will be described with reference to FIGS. 6A to 6C.

FIGS. 6A to 6C depict one example of a beam member of a semiconductor module according to the first embodiment. FIG. 6A is a perspective view schematically depicting a principal part of one example of a beam member of a semiconductor module. FIG. 6B is a plan view schematically depicting a principal part of one example of a beam member of a semiconductor module. FIG. 6C is a side view schematically depicting a principal part of one example of a beam member of a semiconductor module.

FIGS. 6A to 6C schematically depict one example of a beam member 17 of the semiconductor module 10 in a part labelled P in FIG. 3. The beam member 17 is provided between facing side walls of the concave portion 11a of the case 11. Clearance may be provided between the side walls of a concave portion 11a of the case 11 and the side surfaces of a beam member 17 facing the side walls to allow (a part of) adhesive 18d described later to enter. The beam member 17 is a member that is disposed in a concave portion 11a of the case 11 and fixes the multi-layer structure 16 disposed in a concave portion 11a of the case 11 so that the multi-layer structure 16 is interposed and fixed between the beam member 17 and the bottom portion of the concave portion 11a.

As depicted in FIGS. 6A to 6C, the beam member 17 is partially recessed to form a recess 17b on the side that faces the multi-layer structure 16 to be fixed. The recess 17b of the beam member 17 is set at a width and depth capable of accommodating the terminal 15 of the multi-layer structure 16. That is, when the beam member 17 is provided in a concave portion 11a of the case 11, the terminal 15 of a multi-layer structure 16 becomes housed in the recess 17b of the beam member 17. Parts of the side of the beam member 17 facing a multi-layer structure 16 that are not the recess 17b face the insulating sheet 14 of the multi-layer structure 16.

A resin material such as PPS resin, PBT resin, PBS resin, PA resin, or ABS resin is used for the beam member 17. As one example, the same type of resin material as the case 11 is used for the beam member 17. However, it is also possible to use a different resin material to the case 11 for the beam member 17. As one example, a beam member 17 with a recess 17b like that described above may be formed by injection molding using a predetermined resin material.

Next, assembly of the case 11, the multi-layer structures 16, and the beam members 17 of the semiconductor module 10 will be described.

The case 11 and the beam members 17 are both prepared before assembly of the case 11, the multi-layer structures 16, and the beam members 17 commences. That is, the case 11 that includes the concave portions 11a with the recesses 11b as depicted in FIGS. 4A to 4C is formed and prepared for example by injection molding using a predetermined resin material, such as PPS resin. The beam members 17 with the recesses 17b as depicted in FIGS. 6A to 6C are formed and prepared for example by injection molding using a predetermined resin material such as PPS resin.

Before assembly of the case 11, the multi-layer structures 16, and the beam members 17, in addition to the case 11 and the beam members 17, the multi-layer structures 16, that is, the multi-layer structures 16 in which the terminals 13, the insulating sheets 14, and the terminals 15 are stacked in that order, are prepared.

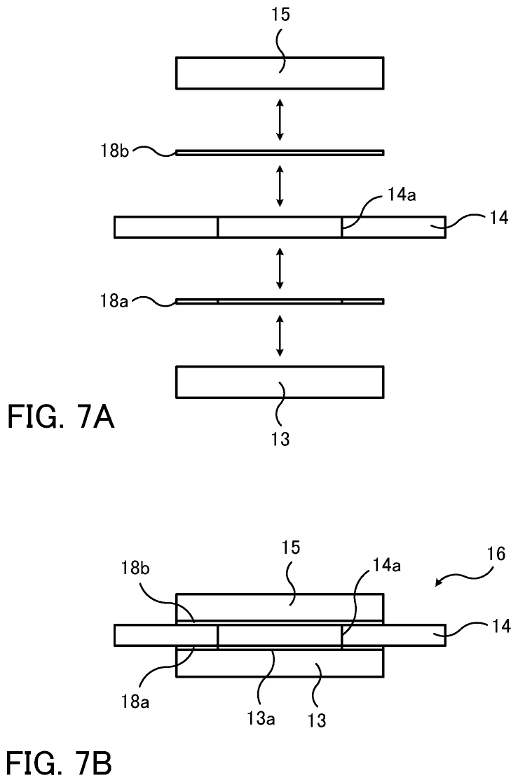

Here, FIGS. 7A and 7B depict one example of a process that prepares a multi-layer structure according to the first embodiment. FIG. 7A is a side view (an exploded side view) of a principal part schematically depicting one example of the terminals, the insulating sheet, and the adhesive before stacking, and FIG. 7B is a side view schematically depicting a principal part of one example of a state after the terminals, the insulating sheets, and the adhesive have been stacked.

As one example, as depicted in FIG. 7A, the terminal 13, the insulating sheet 14 and the terminal 15 that have been formed in advance in predetermined sizes are prepared, and the adhesive 18a and the adhesive 18b are provided between the terminal 13 and the insulating sheet 14 and between the insulating sheet 14 and the terminal 15, respectively. After this, as depicted in FIG. 7B, the terminal 13 and the insulating sheet 14 are bonded using the adhesive 18a, and the insulating sheet 14 and the terminal 15 are bonded using the adhesive 18b.

As the adhesive 18a and the adhesive 18b, it is possible to use an epoxy-based adhesive, a silicone-based adhesive, a ceramic-based adhesive, or the like. As the adhesive 18a and the adhesive 18b, it is possible to use liquid adhesive, but it is also possible to use an adhesive in sheet form. The same kind of adhesive may be used for both the adhesive 18a and the adhesive 18b, or different adhesives may be used. To bond the terminal 13 and the insulating sheet 14 using the adhesive 18a, it is possible to stick a terminal 13 that has been provided in advance with the adhesive 18a onto the insulating sheet 14, or to stick the terminal 13 onto an insulating sheet 14 that has been provided in advance with the adhesive 18a. Likewise, to bond the insulating sheet 14 and the terminal 15 using the adhesive 18b, it is possible to stick a terminal 15 that has been provided in advance with the adhesive 18b onto the insulating sheet 14, or to stick the terminal 15 onto an insulating sheet 14 that has been provided in advance with the adhesive 18b.

As one example, the adhesive 18a interposed between the terminal 13 and the insulating sheet 14 and the adhesive 18b interposed between the insulating sheet 14 and the terminal 15 are cured using a method, such as heating and irradiation with light, that depends on the material(s) used for the adhesive 18a and the adhesive 18b. Alternatively, the adhesive 18a and the adhesive 18b may be in an uncured or semi-cured state during a preparation stage of the multi-layer structure 16 (that is, before the multi-layer structure 16 is disposed in a concave portion 11a of the case 11).

As one example, multi-layer structures 16 like that depicted in FIGS. 7B and FIGS. 5A to 5C, that is, multi-layer structures 16 in each of which the terminal 13, the insulating sheet 14, and the terminal 15 have been stacked in that order, are prepared.

Note that preparation of the case 11, preparation of the beam members 17, and preparation of the multi-layer structures 16 may be performed in any order.

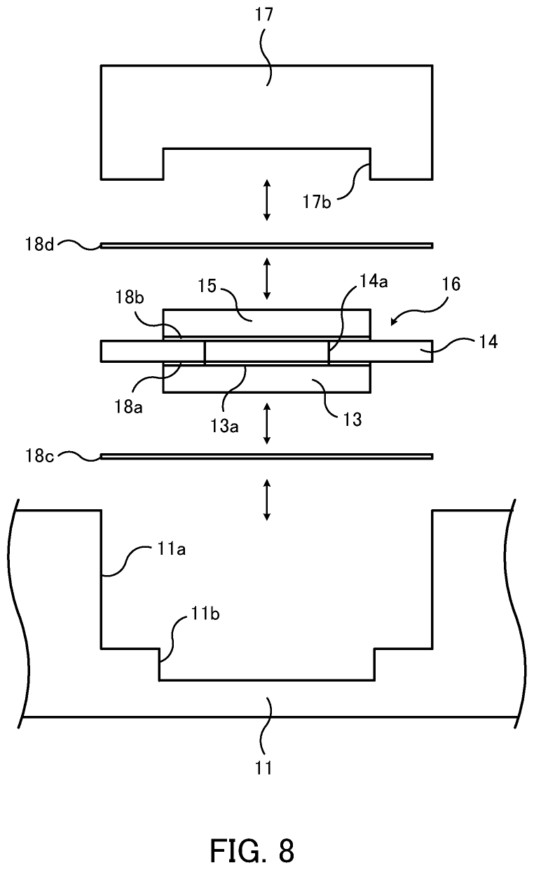

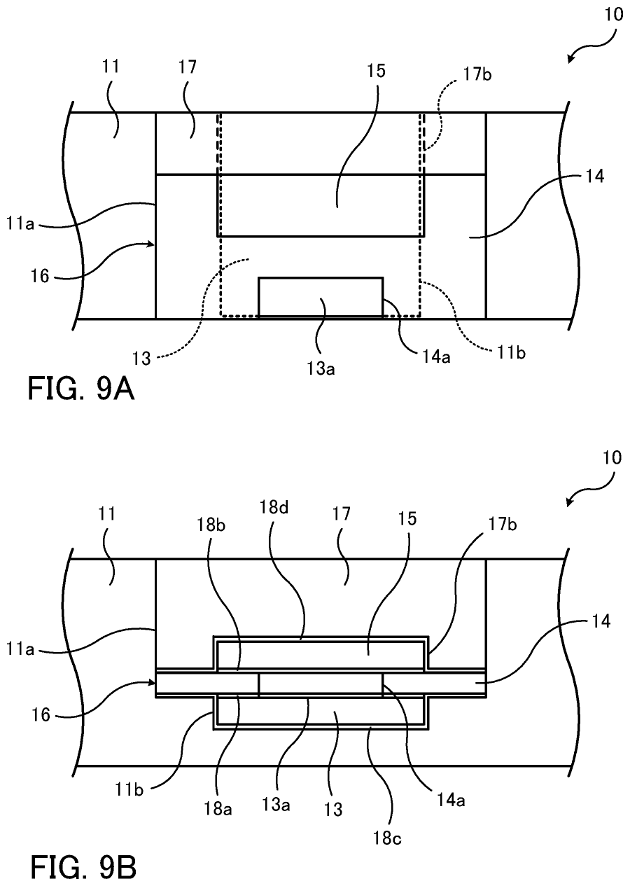

FIG. 8 and FIGS. 9A and 9B depict one example of an assembly process of the case, the multi-layer structures, and the beam members according to the first embodiment. FIG. 8 is a side view (an exploded side view) schematically depicting a principal part of one example of a case, multi-layer structures, beam members, and adhesive before assembly. FIG. 9A is a plan view schematically depicting a principal part of one example state after assembly of the case, multi-layer structure, beam member and adhesive, and FIG. 9B is a side view schematically depicting a principal part of one example of a state after assembly of the case, multi-layer structure, beam member, and adhesive.

As one example, as depicted in FIG. 8, adhesive 18c (first first-adhesive) and adhesive 18d (second first-adhesive) are provided between the concave portion 11a (including the recess 11b of the concave portion 11a) of the case 11 that has been prepared in advance and (the terminal 13 side of) the multi-layer structure 16, and between (the terminal 15 side of) the multi-layer structure 16 and (the recess 17b side of) the beam member 17, respectively. Note that aside from being placed between a multi-layer structure 16 and a beam member 17, the adhesive 18d may also be provided between the side walls of the concave portion 11a of the case 11 and the side surfaces of the beam member 17 provided that there is sufficient clearance. After this, as depicted in FIGS. 9A and 9B, the multi-layer structure 16 is bonded to the concave portion 11a of the case 11 using the adhesive 18c and the beam member 17 is bonded to the multi-layer structure 16 (or to the multi-layer structure 16 and the side walls of the concave portion 11a of the case 11) using the adhesive 18d.

As the adhesive 18c and the adhesive 18d, it is possible to use an epoxy-based adhesive, a silicone-based adhesive, a ceramic-based adhesive, or the like. As the adhesive 18c and the adhesive 18d, it is possible to use liquid adhesive, but it is also possible to use an adhesive in sheet form. The same kind of adhesive may be used for both the adhesive 18c and the adhesive 18d, or different adhesives may be used. To bond the multi-layer structures 16 to the concave portions 11a of the case 11 using the adhesive 18c, it is possible to stick multi-layer structures 16 that have been provided in advance with the adhesive 18c onto the case 11, or to stick the multi-layer structures 16 onto a case 11 that has been provided in advance with the adhesive 18c. To bond the beam members 17 to the multi-layer structures 16 (or to the multi-layer structures 16 and the side walls of the concave portions 11a) using the adhesive 18d, it is possible to stick beam members 17 that have been provided in advance with the adhesive 18d onto the multi-layer structures 16 (or onto the multi-layer structures 16 and the side walls of the concave portions 11a), or to stick the beam members 17 onto multi-layer structures 16 (or onto multi-layer structures 16 and the side walls of the concave portions 11a) that have been provided in advance with the adhesive 18d.

As one example, first, the multi-layer structures 16 are disposed via the adhesive 18c in the concave portions 11a of the case 11. The multi-layer structures 16 are disposed in the concave portions 11a via the adhesive 18c so that the terminals 13 of the multi-layer structures 16 become housed in the recesses 11b of the concave portions 11a in the case 11. After this, the beam members 17 are disposed via the adhesive 18d in the concave portions 11a of the case 11 in which the multi-layer structures 16 have been disposed. The beam members 17 are disposed via the adhesive 18d on the multi-layer structures 16 (or the multi-layer structures 16 and the side walls of the concave portions 11a) so that the terminals 15 of the multi-layer structures 16 are housed in the recesses 17b of the beam members 17. By doing so, the state depicted in FIGS. 9A and 9B is obtained.

Alternatively, the beam members 17 are first disposed via the adhesive 18d on the multi-layer structures 16. The beam members 17 are disposed via the adhesive 18d on the multi-layer structures 16 so that the terminals 15 of the multi-layer structures 16 become housed in the recesses 17b. After this, the multi-layer structures 16 on which the beam members 17 have been disposed via the adhesive 18d are disposed via the adhesive 18c in the concave portions 11a of the case 11. The multi-layer structures 16 are disposed via the adhesive 18c in the concave portions 11a so that the terminals 13 become housed in the recesses 11b of the concave portions 11a in the case 11. The adhesive 18d may also be provided between the beam members 17 and the side walls of the concave portions 11a. By performing the above steps, the state depicted in FIGS. 9A and 9B is obtained.

After the state depicted in FIGS. 9A and 9B has been obtained, the adhesive 18c and the adhesive 18d are cured using a method, such as heating and irradiation with light, that depends on the material(s) used for the adhesive 18c and the adhesive 18d. Before curing of the adhesive 18c and the adhesive 18d or during curing, to suppress the generation of voids and the like, a defoaming process may be performed in a vacuum. When curing the adhesive 18c and the adhesive 18d, to suppress positional displacements of the multi-layer structures 16 and the beam members 17 and/or the generation of regions that are not filled with the adhesive 18c and the adhesive 18d, a process that presses the beam members 17 toward the bottoms of the concave portions 11a of the case 11 may be performed. As one example, the adhesive 18c and the adhesive 18d are cured by heating while being defoamed in a vacuum in a state where the beam members 17 are pressed toward the bottoms of the concave portions 11a in the case 11.

Note that when the adhesive 18a and the adhesive 18b interposed between the insulating sheet 14 and the terminals 13 and 15 are left in an uncured or semi-cured state during the preparation stage of the multi-layer structures 16 depicted in FIGS. 7A and 7B described above, it is possible, when curing the adhesive 18c and the adhesive 18d, to cure the adhesive 18a and the adhesive 18b at the same time as the adhesive 18c and the adhesive 18d.

As described above, the multi-layer structures 16 are disposed via the adhesive 18c in the concave portions 11a of the case 11 so that the multi-layer structures 16 are attached using the adhesive 18c. The beam members 17 are disposed via the adhesive 18d in the concave portions 11a of the case 11 in which the multi-layer structures 16 have been disposed so that the beam members 17 are attached using the adhesive 18d. By doing so, a state is obtained where the multi-layer structures 16 disposed in the concave portions 11a of the case 11 are fixed by the beam members 17.

In this way, by using the method described above, the case 11 including the concave portions 11a is prepared and the multi-layer structure 16 and the beam member 17 are both prepared separately to the case 11. After this, the multi-layer structures 16 that have been prepared separately to the case 11 are disposed in the concave portions 11a of the case 11 and the beam members 17 that have been prepared separately to the case 11 are attached to the concave portions 11a, thereby fixing the multi-layer structures 16 to the concave portions 11a. Accordingly, unlike when the multi-layer structures 16 including the insulating sheets 14 are insertion molded using a case resin material, such as the PPS resin used for the case 11 and/or the beam members 17, which reaches a comparatively high temperature during molding, a situation where the insulating sheets 14 contact the case resin material that reaches a comparatively high temperature during molding is avoided. Since the insulating sheets 14 are prevented from contacting the case resin material that reaches a comparatively high temperature, it is possible to prevent deterioration of the insulating sheets 14, which would result in problems in achieving sufficient insulation between the terminals 13 and the terminals 15 and make it difficult to ensure the reliability of the semiconductor module 10 including the multi-layer structures 16.

When insertion molding is performed, to suppress deterioration of the insulating sheet 14, an insulating material with a certain level of heat resistance relative to the molding temperature (as one example, around 330° C.) of the case resin material that may be contacted during insertion molding is selected as the insulating material of the insulating sheet 14. On the other hand, with the method described above that separately prepares and then assembles the case 11, the multi-layer structures 16, and the beam members 17, since contact between the insulating sheet 14 and the case resin material at a comparatively high temperature, such as a molding temperature, is avoided, it is possible to select an insulating material with a lower withstand temperature than the molding temperature of the case resin material as the insulating sheet 14. As one example, it is possible to select an insulating material capable of withstanding the curing temperatures of the adhesive 18a, the adhesive 18b, the adhesive 18c, and the adhesive 18d and/or the mounting temperature (as one example, around 220° C.) of components such as semiconductor elements that are mounted on the semiconductor module 10. Accordingly, it is possible to greatly increase the range of insulating materials that are able to be selected for use as the insulating sheets 14.

Also with the method described above that separately prepares the case 11, the multi-layer structures 16, and the beam members 17 and performs assembly using the adhesive 18c and the adhesive 18d, the spaces between the case 11 and the multi-layer structures 16 are filled with the adhesive 18c and the spaces between the multi-layer structures 16 and the beam members 17 are filled with the adhesive 18d. This avoids the formation of gaps between the case 11 and the multi-layer structures 16 and the formation of gaps between the multi-layer structures 16 and the beam members 17. Since a defoaming process is performed in a vacuum during curing, the formation of gaps is further suppressed. By suppressing the formation of gaps, the risk of partial discharge is suppressed. Note that to effectively suppress the risk of partial discharge, it is preferable to provide no clearance between the side walls of the concave portions 11a of the case 11 and the side surfaces of the beam members 17 that face the side walls or alternatively to fill any clearance provided between the side walls and the side surfaces with the adhesive 18d.

It is also possible to adjust the thickness of the adhesive 18c that fills the spaces between the case 11 and the multi-layer structures 16, and the thicknesses of the adhesive 18a and the adhesive 18b between the insulating sheets 14 of the multi-layer structures 16 and the terminals 13 and 15. By adjusting the thicknesses of the adhesive 18c and/or the adhesive 18a and the adhesive 18b in this way, it is possible to adjust the height positions of the terminals 13 and the terminals 15 relative to the bottom of the concave portions 11a of the case 11. By adjusting the height positions of the terminals 13 and the terminals 15, it is possible to adjust the connecting heights of the insulating substrate or semiconductor elements housed in the case 11 or of components connected to the insulating substrate and/or semiconductor elements.

### Second Embodiment

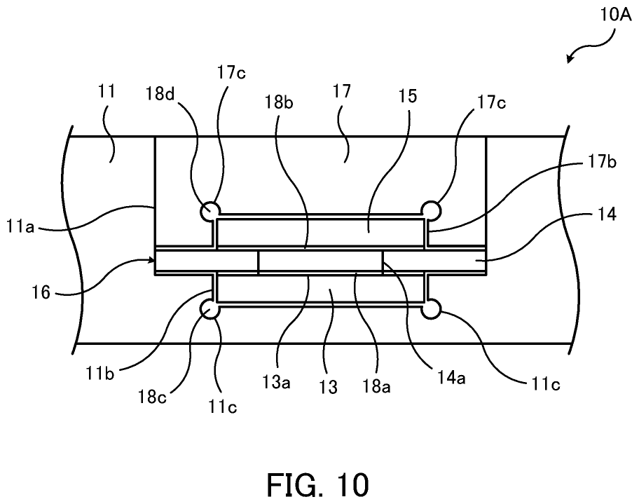

FIG. 10 depicts one example of a semiconductor module according to a second embodiment. FIG. 10 is a side view schematically depicting a principal part of one example of a semiconductor module.

A semiconductor module (hereinafter also referred to as the “semiconductor device”) 10A depicted in FIG. 10 is configured with channels (grooves) 11c, which communicate with the recess 11b and extend in the depth direction relative to the plane of the drawing in FIG. 10, formed in the recess 11b provided in each concave portion 11a of the case 11 and with channels (grooves) 17c, which extend in the depth direction of the plane of the drawing in FIG. 10 formed in the recess 17b provided in each beam member 17. The channels 11c in each concave portion 11a of the case 11 are formed so as to communicate with the recess 11b in the concave portion 11a and the channels 17c of each beam member 17 are formed so as to communicate with the recess 17b of the beam member 17. By having the configuration described above, the semiconductor module 10A differs to the semiconductor module 10 according to the first embodiment described earlier.

By having the channels 11c formed in the recesses 11b of the concave portions 11a in the case 11, it is possible with the semiconductor module 10A for excess amounts of the adhesive 18c that attaches the multi-layer structures 16 to the concave portions 11a to accumulate in the channels 11c. Since it is possible for excess amounts of the adhesive 18c to accumulate in the channels 11c, it is possible to avoid a situation where the height positions of the terminals 13 and the terminals 15 of the multi-layer structures 16 relative to the bottoms of the concave portions 11a of the case 11 become higher than predetermined positions due to the thicknesses of excess amounts of the adhesive 18c. By doing so, it is possible to suppress displacements in the connecting heights between the terminals 13 and terminals 15 of the multi-layer structures 16 and the insulating substrate or semiconductor elements housed in the case 11 or components connected to the insulating substrate and/or semiconductor elements.

Also, by having the channels 17c formed in the recesses 17b of the beam members 17, it is possible with the semiconductor module 10A for excess amounts of the adhesive 18d that attaches the beam members 17 to the multi-layer structures 16 (or to the multi-layer structures 16 and the case 11) to accumulate in the channels 17c. Since it is possible for excess amounts of the adhesive 18d to accumulate in the channels 17c, it is possible to avoid a situation where the height positions of the beam members 17 relative to the case 11 become higher than a predetermined position due to the thicknesses of excess amounts of the adhesive 18d. By doing so, it is possible to avoid problems such as visual imperfections due to the beam member 17 sticking out of the case 11 and/or a cover rattling when a cover is provided on the case 11.

Note that an example configuration where the channels 11c and the channels 17c are formed in the concave portions 11a of the case 11 and the beam members 17 is described here. As alternatives, out of the concave portions 11a and the beam members 17, it is possible to form the channels 11c in only the concave portions 11a and have excess amounts of the adhesive 18c accumulate in the channels 11c, or to form the channels 17c in only the beam members 17 and have excess amounts of the adhesive 18d accumulate in the channels 17c.

The positions, sizes, and number of the channels 11c formed in the concave portions 11a of the case 11 are not limited to the example described above and so long as it is possible for excess amounts of the adhesive 18c to accumulate, various changes may be made to the positions, sizes, and number of the channels 11c. Likewise, the positions, sizes, and number of the channels 17c formed in the beam members 17 are not limited to the example described above and so long as it is possible for excess amounts of the adhesive 18d to accumulate, various changes may be made to the positions, sizes, and number of the channels 17c.

In the same way as the semiconductor module 10 according to the first embodiment described earlier, it is possible to connect the semiconductor module 10A to other electronic components, such as the capacitor 20, using the terminals 13 and the terminals 15 of the multi-layer structures 16 that are provided with the insulating sheets 14 in between.

### Third Embodiment

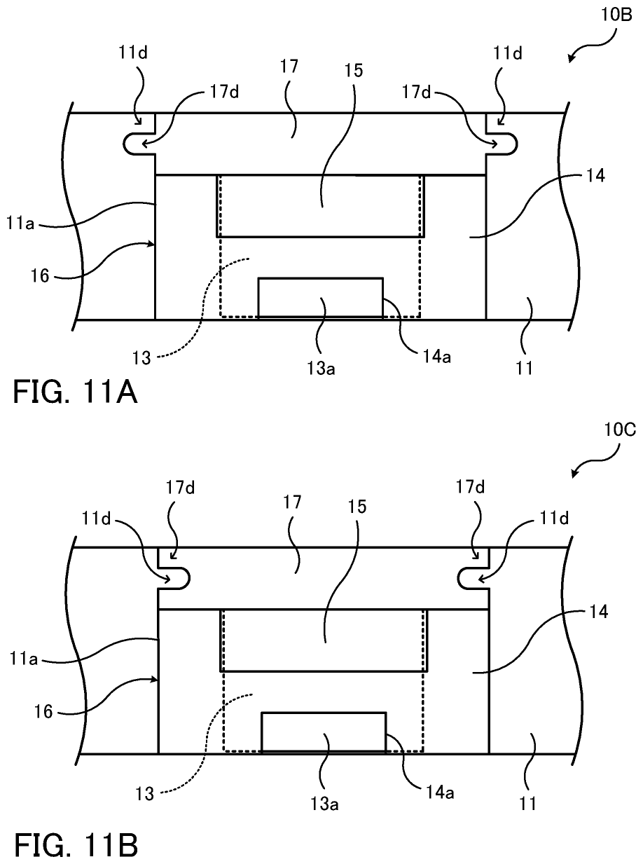

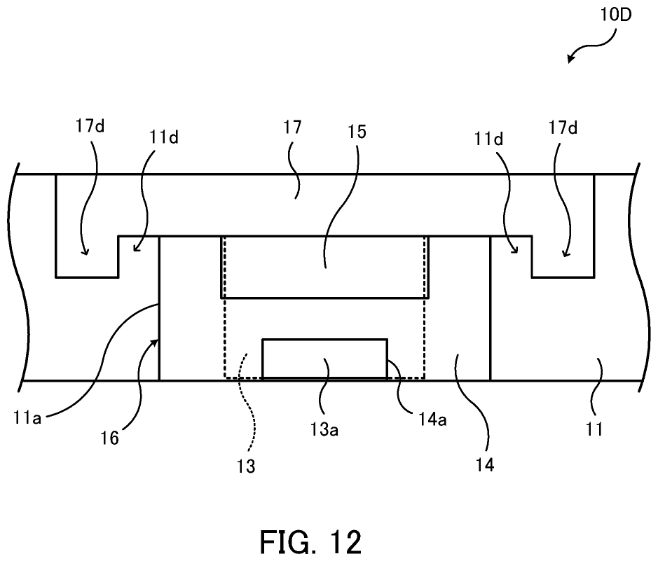

FIGS. 11A and 11B and FIG. 12 depict examples of a semiconductor module according to a third embodiment. FIGS. 11A and 11B and FIG. 12 are plan views schematically depicting principal parts of examples of a semiconductor module.

A semiconductor module (hereinafter also referred to as the “semiconductor device”) 10B depicted in FIG. 11A has locking portions 17d that lock onto the case 11 provided on each beam member 17 and has mating portions 11d that mate with the locking portions 17d of the beam members 17 provided on the case 11. By having the configuration described above, the semiconductor module 10B differs to the semiconductor module 10 according to the first embodiment described earlier. Locking portions that correspond to the mating portions 11d may also be formed on the insulating sheet 14 disposed below the beam member 17. By using this configuration, it becomes possible to easily position the insulating sheets 14 on the case 11.

In the semiconductor module 10B, locking portions 17d that protrude from the side surfaces that face the side walls of the concave portions 11a of the case 11 in plan view are provided as the locking portions 17d of the beam member 17, and mating portions 11d that are recessed from the side walls of the concave portions 11a of the case 11 in plan view are provided as the mating portions 11d of the case 11. With the semiconductor module 10B, when the beam members 17 are attached to the concave portions 11a of the case 11, the locking portions 17d of the beam members 17 are inserted into and mate with the mating portions 11d of the case 11. By doing so, the beam members 17 are attached to the case 11 that has the multi-layer structures 16 disposed in the concave portions 11a in a state where positional displacements are suppressed. In addition, due to the locking portions 17d mating with the mating portions 11d of the case 11, the strength of attachment of the beam members 17 is increased and it is possible to avoid detachment of the beam members 17 due to external forces.

A semiconductor module (hereinafter also referred to as the “semiconductor device”) 10C depicted in FIG. 11B is configured to include locking portions 17d that are recessed from the side surfaces of the beam members 17 that face the side walls of the concave portions 11a of the case 11 in plan view as the locking portions 17d of the beam member 17 and mating portions 11d that protrude from the side walls of the concave portions 11a of the case 11 in plan view as the mating portions 11d of the case 11. Concave portions that correspond to the mating portions 11d may also be formed in the insulating sheets 14 disposed below the beam members 17. By using this configuration, it becomes possible to easily position the insulating sheets 14 on the case 11. By having the configuration described above, the semiconductor module 10C differs to the semiconductor module 10 according to the first embodiment described earlier.

With the semiconductor module 10C, when the beam members 17 are attached to the concave portions 11a of the case 11, the mating portions 11d of the case 11 are inserted into and mate with the locking portions 17d of the beam members 17. By doing so, the beam members 17 are attached to the case 11 that has the multi-layer structures 16 disposed in the concave portions 11a in a state where positional displacements are suppressed. In addition, due to the locking portions 17d mating with the mating portions 11d of the case 11, the strength of attachment of the beam members 17 is increased and it is possible to avoid detachment of the beam members 17 due to external forces.

A semiconductor module (hereinafter also referred to as the “semiconductor device”) 10D depicted in FIG. 12 includes beam members 17 that are larger than the multi-layer structures 16 disposed in the concave portions 11a of the case 11. The semiconductor module 10D is configured so that locking portions 17d that protrude toward an inside of a frame of the case 11 are provided on end portions of the beam members 17, and mating portions 11d that are recessed toward the inside of the frame and mate with the locking portions 17d of the beam member 17 are provided on the case 11. By having the configuration described above, the semiconductor module 10D differs to the semiconductor module 10 according to the first embodiment described earlier.

With the semiconductor module 10D, in the same way as described above, the locking portions 17d of the beam members 17 are inserted into and mate with the mating portions 11d of the case 11. By doing so, the beam members 17 are attached with high strength to the case 11 in a state where positional displacements are suppressed.

Note that in the semiconductor module 10B, the semiconductor module 10C, and the semiconductor module 10D, sufficient clearance for the adhesive 18d to enter may be provided between the locking portions 17d and the mating portions 11d.

In the semiconductor module 10B, the semiconductor module 10C, and the semiconductor module 10D, the concave portions 11a of the case 11 and the beam members 17 may be provided with the channels 11c in which the adhesive 18c accumulates and the channels 17c in which the adhesive 18d accumulates in accordance with the example described in the second embodiment above.

In the same way as the semiconductor module 10 described in the first embodiment, it is possible to connect the semiconductor module 10B, the semiconductor module 10C, and the semiconductor module 10D to other electronic components, such as the capacitor 20, using the terminals 13 and the terminals 15 of the multi-layer structures 16 provided with the insulating sheets 14 in between.

### Fourth Embodiment

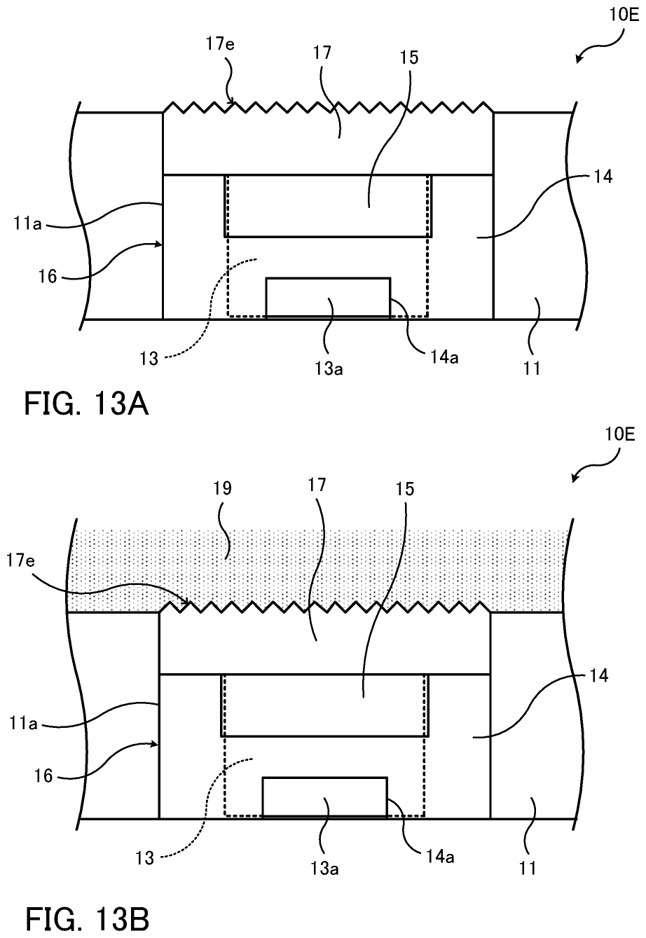

FIGS. 13A and 13B depict one example of a semiconductor module according to a fourth embodiment. FIG. 13A is a plan view schematically depicting a principal part of one example of a semiconductor module, and FIG. 13B is a plan view schematically depicting a principal part of one example of a semiconductor module where encapsulating resin is provided inside a case.

The semiconductor module (also referred to as the “semiconductor device”) 10E depicted in FIG. 13A is configured to include a part that has been roughened (hereinafter referred to as the “roughened portion”) 17e provided on the surface of each beam member 17 that becomes the inside of the case 11. By having the configuration described above, the semiconductor module 10E differs to the semiconductor module 10 according to the first embodiment described earlier.

As one example, it is possible to form the roughened portion 17e of each beam member 17 using a mold provided with a part corresponding to the roughened portion 17e when molding the beam members 17 by injection molding. As alternatives, it is possible to form the roughened portions 17e of the beam members 17 by processing the surface that forms the inner surface of the case 11 using an appropriate processing method such as laser processing, sandblasting, or etching after the beam members 17 have been molded by injection molding. By providing the roughened portion 17e on the surface of each beam member 17 that forms the inside of the case 11, the surface area of this surface is increased.

In the semiconductor module 10E, an insulating substrate and components such as semiconductor elements mounted on the insulating substrate are housed inside the case 11. As depicted in FIG. 13B, as one example, the insulating substrate and/or semiconductor elements housed inside the case 11 are encapsulated with encapsulating resin 19, such as epoxy resin or silicone resin. When the inside of the case 11 is encapsulated with the encapsulating resin 19 in this way, due to the roughened portion 17e provided on the surface of each beam member 17 that forms the inside of the case 11 increasing the surface area of this surface, the strength of attachment between the beam members 17 and the encapsulating resin 19 is increased.

Note that with the semiconductor module 10 described in the first embodiment, the semiconductor module 10A described in the second embodiment, and the semiconductor module 10B, the semiconductor module 10C, and the semiconductor module 10D described in the third embodiment also, it is possible to encapsulate the inside of the case 11, in which the insulating substrate and the semiconductor elements and the like are housed, with the encapsulating resin 19 in the same way as the semiconductor module 10E described in the fourth embodiment.

Also, in the semiconductor module 10E, the concave portions 11a of the case 11 and the beam members 17 may be provided with the channels 11c in which the adhesive 18c accumulates and the channels 17c in which the adhesive 18d accumulates in accordance with the example described in the second embodiment above.

It is also possible for the semiconductor module 10E to be configured so that the mating portions 11d and the locking portions 17d are provided on the case 11 and the beam members 17 in accordance with the example described in the third embodiment above.

In the same way as the semiconductor module 10 described in the first embodiment, it is possible to connect the semiconductor module 10E to other electronic components, such as the capacitor 20, using the terminals 13 and the terminals 15 of the multi-layer structures 16 provided with the insulating sheets 14 in between.

### Fifth Embodiment

The configuration of the multi-layer structures 16 in which the terminals 13, the insulating sheets 14, and the terminals 15 are stacked in that order is not limited to the configurations described above in the first to fourth embodiments. A different example configuration of the multi-layer structures 16 will now be described as a fifth embodiment.

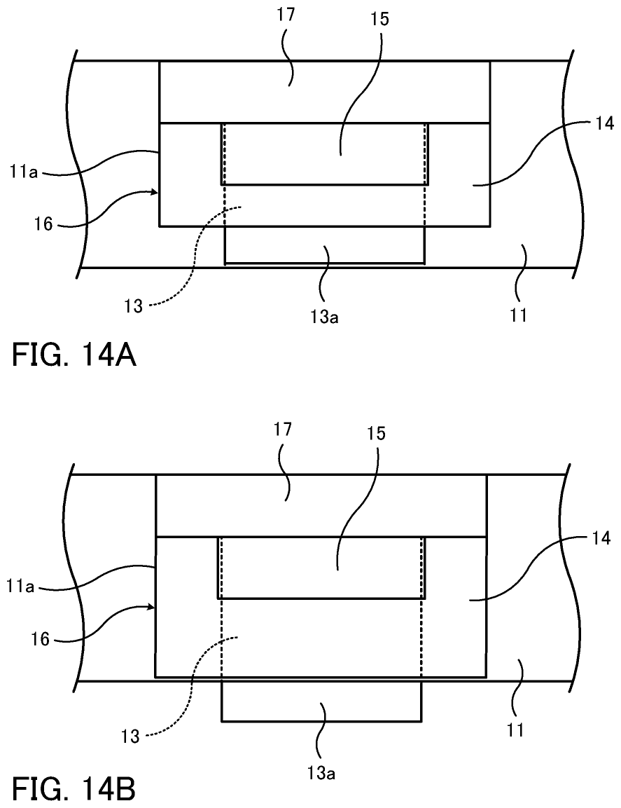

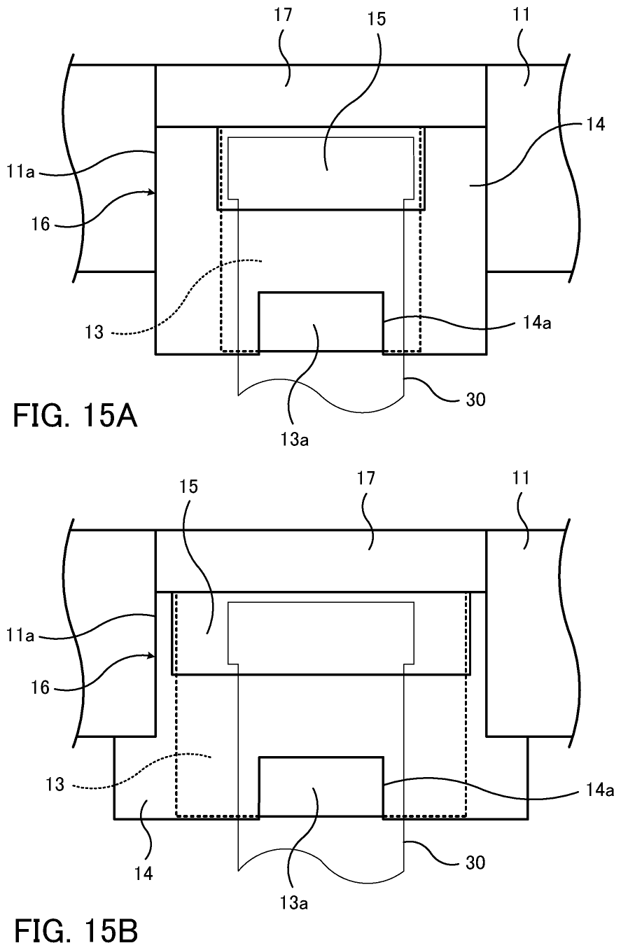

FIGS. 14A and 14B and FIGS. 15A and 15B depict example configurations of multi-layer structures of semiconductor modules according to the fifth embodiment. FIGS. 14A and 14B and FIGS. 15A and 15B are plan views schematically depicting principal parts of the respective examples of semiconductor modules.

As one example, as depicted in FIG. 14A, in each multi-layer structure 16, the insulating sheet 14 may be formed without a cutout portion 14a. So long as the terminal 13 and the terminal 15 are provided with the insulating sheet 14 in between, a front end portion of the terminal 13 that forms an outside of the case 11 is exposed from the insulating sheet 14, and the terminal 13, the insulating sheet 14, and the terminal 15 are stacked so that the front end portion of the terminal 13, the insulating sheet 14, and the terminal 15 are in a stepped arrangement when viewed in cross section, the insulating sheet 14 may omit the cutout portion 14a. The front end portion of the terminal 13 that is exposed from the insulating sheet 14 functions as the connecting region 13a that is to be connected to a terminal of an electronic component, such as the capacitor 20.

Since the multi-layer structure 16 depicted in FIG. 14A includes an insulating sheet 14 that is not provided with a cutout portion 14a, it is easier to prepare and dispose the insulating sheet 14.

It is possible to use a configuration like that depicted in FIG. 14A as the multi-layer structure 16.

Also, as another example, the terminal 13 of each multi-layer structure 16 may be provided so that the front end portion of the terminal 13 protrudes from an outer edge of the concave portion 11a of the case 11 as depicted in FIG. 14B. Here, the insulating sheet 14 is provided in a concave portion 11a of the case 11 so that the front end portion of the terminal 13 that protrudes from the outer edge of the concave portion 11a of the case 11 is exposed. The front end portion of the terminal 13 that protrudes from the outer edge of the concave portion 11a of the case 11 and is exposed from the insulating sheet 14 functions as the connecting region 13a to be connected to the terminal of an electronic component, such as the capacitor 20.

In the multi-layer structure 16 depicted in FIG. 14B, since the connecting region 13a of the terminal 13 protrudes outside the concave portion 11a of the case 11, it is possible to prevent damage to the concave portion 11a of the case 11 situated below the terminal 13 when the terminal of an electronic component, such as the capacitor 20, is connected by laser welding or the like to the connecting region 13a.

It is possible to use a configuration like that depicted in FIG. 14B as the multi-layer structure 16.

Also, as depicted in FIG. 15A, the multi-layer structure 16 may be configured so that the front end portion of the terminal 13 protrudes from the outer edge of the concave portion 11a of the case 11 and is covered with the insulating sheet 14 that has the cutout portion 14a. The part of the terminal 13 that extends from the outer edge of the concave portion 11a of the case 11 and is exposed from the cutout portion 14a of the insulating sheet 14 functions as the connecting region 13a that is connected to the terminal of an electronic component, such as the capacitor 20.

In the multi-layer structure 16 depicted in FIG. 15A, since the connecting region 13a of the terminal 13 protrudes outside the concave portion 11a of the case 11, it is possible to avoid damage to the concave portion 11a of the case 11 situated below the terminal 13 when the terminal of an electronic component, such as the capacitor 20, is connected to the connecting region 13a by laser welding or the like.

Also, in the multi-layer structure 16 depicted in FIG. 15A, aside from the part that forms the connecting region 13a, the front end portion of the terminal 13 that protrudes from the outer edge of the concave portion 11a of the case 11 is covered with the insulating sheet 14, which is wider, in plan view, than the terminal 13. With this configuration, as described above for example, sufficient insulation distance (or “creepage distance”) across the insulating sheet 14 is achieved between the terminal 13 (which is an N terminal) and the connector member 30 (or “P terminal connecting terminal”, indicated out of convenience with thin solid lines in FIG. 15A) which is connected to the terminal 15 (the P terminal) when an electronic component such as the capacitor 20 is connected and becomes positioned above the terminal 13.

It is possible to use the configuration depicted in FIG. 15A as the multi-layer structure 16.

As depicted in FIG. 15B, the multi-layer structure 16 may be configured so that the front end portion of the terminal 13 protrudes from the outer edge of the concave portion 11a of the case 11 and is covered with the insulating sheet 14 that includes the cutout portion 14a, with the terminal 13 being wider in plan view than the configuration depicted in FIG. 15A described above. The insulating sheet 14 is shaped so that a region that protrudes from the outer edge of the concave portion 11a of the case 11 is made even wider in plan view than the terminal 13 that has been widened.

With a multi-layer structure 16 like that depicted in FIG. 15B also, it is possible to prevent damage to the concave portion 11a of the case 11 situated below the terminal 13 when the terminal of an electrical component, such as the capacitor 20, is connected to the connecting region 13a that protrudes outside the concave portion 11a of the case 11 by laser welding or the like.

In addition, with a multi-layer structure 16 like that depicted in FIG. 15B, as described above for example, sufficient insulation distance (or “creepage distance”) across the insulating sheet 14 is achieved between the terminal 13 (which is an N terminal) and the connector member 30 (or “P terminal connecting terminal”, indicated out of convenience with thin solid lines in FIG. 15B) which is connected to the terminal 15 (the P terminal) when an electronic component such as the capacitor 20 is connected and becomes positioned above the terminal 13. In addition, according to the multi-layer structure 16 depicted in FIG. 15B, since the terminal 13 (the N terminal) is wider than the connector member 30 (the P terminal connector member) connected to the terminal 15 (P terminal) and the cross-sectional area of the terminal 13 is larger than the configuration in FIG. 15A described above, the inductance at the part of the terminal 13 connected to an electronic component, such as the capacitor 20, is reduced. According to the multi-layer structure 16 depicted in FIG. 15B, it is possible to reduce inductance while achieving a sufficient insulation distance.

It is possible to use the configuration depicted in FIG. 15B as the multi-layer structure 16.

Note that in the semiconductor module 10 described in the first embodiment, the semiconductor module 10A described in the second embodiment, the semiconductor module 10B, the semiconductor module 10C, and the semiconductor module 10D described in the third embodiment, and the semiconductor module 10E described in the fourth embodiment also, it is possible to use multi-layer structures 16 like those depicted in FIGS. 14A and 14B and FIGS. 15A and 15B.

### Sixth Embodiment

A method for manufacturing (that is, an assembly method of) the semiconductor module 10 and the like described above will now be described as a sixth embodiment.

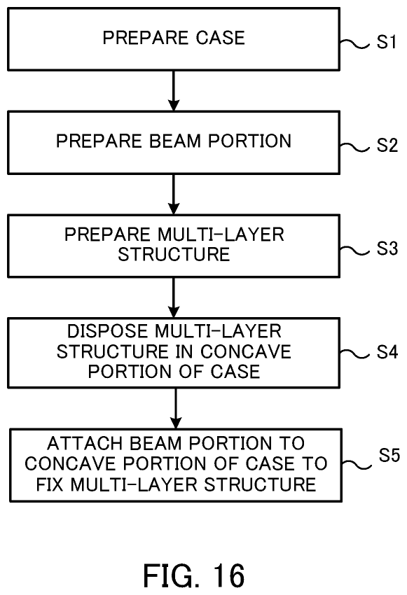

FIG. 16 depicts one example of a method for manufacturing a semiconductor module according to the sixth embodiment.

First, the case 11 equipped with the concave portions 11a including the recesses 11b is prepared (step S1). As one example, the case 11 is formed as depicted in FIGS. 4A to 4C described above by injection molding using a predetermined resin material, such as PPS resin. Alternatively, as depicted in FIG. 10 described above, a case 11 that has the channels 11c provided in the recesses 11b of the concave portions 11a as depicted in FIG. 10 described above is formed. As another alternative, a case 11 provided with the mating portions 11d as depicted in FIGS. 11 and 12 described above is formed.

The beam members 17 that each include the recess 17b that is to be disposed in a concave portion 11a of the case 11 are prepared separately to the case 11 (step S2). As one example, beam members 17 like that depicted in FIGS. 6A to 6C described above is formed by injection molding using a predetermined resin material such as PPS resin, and as one example, the same resin material as the resin material used as the case 11. Alternatively, beam members 17 that each have the channels 17c provided in the recess 17b like that depicted in FIG. 10 described above are formed. Alternatively, beam members 17 provided with locking portions 17d like those depicted in FIGS. 11A and 11B and FIG. 12 described above are formed. As another alternative, beam members 17 provided with a roughened portion 17e like that depicted in FIGS. 13A and 13B described above are formed.

The multi-layer structures 16 to be disposed in the concave portions 11a of the case 11, that is, multi-layer structures 16 in which the terminal 13, the insulating sheet 14, and the terminal 15 are stacked in that order, are prepared separately to the case 11 and the beam members 17 (step S3). As one example, as depicted in FIGS. 5 and 7 described above, the terminal 13 is provided via the adhesive 18a on one surface of the insulating sheet 14 and the terminal 15 is provided via the adhesive 18b on the other surface of the insulating sheet 14. Alternatively, multi-layer structures 16 like those depicted in FIGS. 14A to 15B described above are prepared.

Note that preparation of the case 11 (step S1), preparation of the beam members 17 (step S2), and preparation of the multi-layer structures 16 (step S3) may be performed in any order.

After the case 11, the beam members 17, and the multi-layer structures 16 have been prepared, the multi-layer structures 16 are disposed via the adhesive 18c in the concave portions 11a of the case 11 according to the example in FIG. 8 and FIGS. 9A and 9B described above (step S4).

In addition, the beam members 17 are disposed via the adhesive 18d in the concave portions 11a of the case 11 in which the multi-layer structures 16 have been disposed to attach the beam members 17 to the concave portions 11a according to the example in FIGS. 8 and FIGS. 9A and 9B described above (step S5). By doing so, the multi-layer structures 16 are fixed to the concave portions 11a of the case 11.

When the mating portions 11d are provided on the case 11 and the locking portions 17d are provided on the beam member 17, during disposing of the beam members 17 in the concave portions 11a of the case 11, the locking portions 17d mate with and are locked to the mating portions 11d. When the beam members 17 are attached to the concave portions 11a of the case 11 in which the multi-layer structures 16 have been disposed, as one example, the beam members 17 are attached by applying heat while defoaming in a vacuum.

Note that the disposing of the multi-layer structures 16 (step S4) and the disposing of the beam members 17 (step S5) may be achieved by providing the beam members 17 via the adhesive 18d on the multi-layer structures 16 and then providing the multi-layer structures 16, on which the beam members 17 have been provided in this way, via the adhesive 18c in the concave portions 11a of the case 11.

As one example, a method like steps S1 to S5 is used to manufacture the semiconductor module 10 and the like described above.

The manufactured semiconductor module 10 or the like may be connected for example to the capacitor 20 using the terminals 13 and the terminals 15 of the multi-layer structures 16 that have the insulating sheets 14 provided in between in accordance with the example depicted in FIGS. 1 and 2 described above. By doing so, a semiconductor device 1 like that depicted in FIGS. 1 and 2 described above is obtained. Note that so long as the component is connected using the terminals 13 and the terminals 15 of the multi-layer structures 16, it is possible to connect other electronic components to the semiconductor module 10 and the like, without the connected component being limited to the capacitor 20.

An example configuration is described above where the multi-layer structures 16 are attached to the concave portions 11a of the case 11 using the adhesive 18c and the beam members 17 is attached to the concave portion 11a of the case 11 using the adhesive 18d. As an alternative, it is also possible to provide an encapsulating material that has an adhesive property or no adhesive property and is capable of filling gaps between the multi-layer structures 16 and the concave portions 11a of the case 11 or the beam members 17, and to fix the beam members 17 to the case 11 by mating or by screw engagement.

According to the present embodiments, it is possible to realize a semiconductor device with high reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a case that has a side wall to form a frame, the side wall having a concave portion;
a multi-layer structure in which a first terminal, an insulating sheet, and a second terminal are stacked in that order and which is disposed on the concave portion; and
a beam member that is attached to the concave portion of the case to fix the multi-layer structure disposed on the concave portion.

2. The semiconductor device according to claim 1, further comprising a first first-adhesive interposed between the concave portion of the case and the multi-layer structure and a second first-adhesive interposed between the multi-layer structure and the beam member.

3. The semiconductor device according to claim 1, wherein the multi-layer structure further includes a first second-adhesive interposed between the first terminal and the insulating sheet and a second second-adhesive interposed between the insulating sheet and the second terminal.

4. The semiconductor device according to claim 1, wherein
the multi-layer structure is disposed such that the first terminal is positioned at a bottom side of the concave portion of the case and the second terminal is positioned at a beam member side,
the concave portion of the case includes, at the bottom side, a first recess in which the first terminal of the multi-layer structure is housed, and
the beam member includes a second recess in which the second terminal of the multi-layer structure is housed.

5. The semiconductor device according to claim 4, wherein
the case includes a first groove that communicates with the first recess, and
the beam member includes a second groove that communicates with the second recess.

6. The semiconductor device according to claim 1, wherein
the beam member includes a locking portion, and
the case includes a mating portion with which the locking portion of the beam member engages.

7. The semiconductor device according to claim 1, wherein a material of the beam member is a same material as a material of the case.

8. The semiconductor device according to claim 1, wherein the beam member attached to the concave portion of the case includes a roughened surface that forms a part of an inner surface of the side wall of the case.

9. A method for manufacturing a semiconductor device, comprising:
preparing a case that has a side wall to form a frame, the side wall having a concave portion;
preparing a beam member capable of being disposed in the concave portion of the case;
preparing a multi-layer structure in which a first terminal, an insulating sheet, and a second terminal are stacked in that order;
disposing the multi-layer structure in the concave portion of the case; and
attaching the beam member to the concave portion of the case in which the multi-layer structure is disposed to fix the multi-layer structure.

10. The method for manufacturing a semiconductor device according to claim 9, further comprising bonding the concave portion of the case and the multi-layer structure together using a first first-adhesive and bonding the multi-layer structure and the fixed member together using a second first-adhesive.

11. The method for manufacturing a semiconductor device according to claim 9, wherein the preparing of the multi-layer structure includes bonding the first terminal and the insulating sheet together using a first second-adhesive and bonding the insulating sheet and the second terminal together using a second second-adhesive.

12. The method for manufacturing a semiconductor device according to claim 9, wherein
the disposing of the multi-layer structure includes disposing the multi-layer structure such that the first terminal is housed in a first recess provided in a bottom of the concave portion of the case, and
the attaching of the beam member to the concave portion of the case includes attaching the beam member such that the second terminal of the multi-layer structure disposed in the concave portion is housed in a second recess provided in the beam member.

13. The method for manufacturing a semiconductor device according to claim 9, wherein
the beam member includes a locking portion,
the case includes a mating portion with which the locking portion of the beam member engages, and
the attaching of the beam member to the concave portion of the case includes engaging the locking portion of the beam member with the mating portion of the case.
